(19) United States
(12) Patent Application Publication
(10) Pub. No.: US 2018/0148841 A1
(43) Pub. Date: May 31, 2018

(54) SHOWER HEAD AND ROLL-TO-ROLL PLASMA-PROCESSING APPARATUS INCLUDING THE SAME

(71) Applicant: LG Display Co., Ltd., Seoul (KR)

(72) Inventors: Shin-Bok LEE, Seoul (KR); Yun-Ho KOOK, Paju-si (KR)

(21) Appl. No.: 15/826,263

(22) Filed: Nov. 29, 2017

(30) Foreign Application Priority Data
Nov. 30, 2016 (KR) 10-2016-0162010

(51) Int. Cl. C23C 16/455; C23C 16/50; C23C 16/54

(52) U.S. Cl. CPC C23C 16/45565; C23C 16/545; C23C 16/45578; C23C 16/50

(57) ABSTRACT

Disclosed are a shower head capable of improving plasma uniformity and a roll-to-roll plasma-processing apparatus including the same. The shower head includes a body including a plurality of flow channels provided therein and a front surface having a concave shape, and a plurality of spray holes formed in the front surface and having the same diameter as one another. Each of the spray holes is connected to a corresponding one of the flow channels so that reaction gas supplied through the flow channels is sprayed from the front surface through the spray holes.

This application claims the benefit of Korean Patent Application No. 10-2016-0162010, filed on Nov. 30, 2016, which is hereby incorporated by reference as if fully set forth herein.

### BACKGROUND

### Technical Field

The present disclosure relates to a shower head and a roll-to-roll plasma-processing apparatus including the same, and more particularly to a shower head capable of improving plasma uniformity and a roll-to-roll plasma-processing apparatus including the same.

### Description of the Related Art

In a process of manufacturing a semiconductor device or a display device, a plasma-processing apparatus, for example, a plasma-enhanced chemical vapor deposition (PECVD) apparatus, is used to form a thin film on a substrate.

A plasma-processing apparatus is an apparatus for forming a thin film on a substrate by turning reaction gas into plasma by activating the same. Such a plasma-processing apparatus may be classified into a capacitive-coupled plasma-processing apparatus and an inductive-coupled plasma-processing apparatus in accordance with the method of generating plasma.

Recently, a flexible display device, which uses a flexible substrate, such as a film, instead of a fragile and non-flexible glass substrate, has been developed. A flexible display device is manufactured in the manner of unwinding a flexible substrate wound around a roller so that the flexible substrate is introduced into a deposition chamber, that is, a plasma-processing apparatus, and of forming a thin film on the flexible substrate.

The plasma-processing apparatus includes a drum and a shower head. The drum and the shower head are disposed inside the plasma-processing apparatus. The drum has a cylindrical shape. A flexible substrate is introduced into the plasma-processing apparatus along the outer circumferential surface of the drum. The shower head is disposed adjacent to a portion of the outer circumferential surface of the drum. When RF voltage from an external device is applied to the shower head, reaction gas is sprayed from the front surface of the shower head. The reaction gas sprayed from the shower head is excited to form plasma, with a result that a thin film is deposited on the flexible substrate.

The shower head of the plasma-processing apparatus needs to be formed such that the front surface thereof is concave so as to correspond to the cylindrical-shaped drum. However, there is a problem in that the amount of reaction gas sprayed from the upper portion of the shower head and the amount of reaction gas sprayed from the middle portion of the shower head are different, which degrades plasma uniformity and consequently reduces the deposition rate and the density of the thin film.

### BRIEF SUMMARY

Accordingly, the present disclosure is directed to a shower head and a roll-to-roll plasma-processing apparatus including the same that substantially obviate one or more problems due to limitations and disadvantages of the related art.

In various embodiments, the present disclosure provides a shower head capable of improving plasma uniformity and a roll-to-roll plasma-processing apparatus including the same.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the various purposes of the disclosure, as embodied and broadly described herein, a shower head for a plasma processing apparatus includes a body including a plurality of flow channels provided therein and a front surface having a concave shape, and a plurality of spray holes formed in the front surface.

The spray holes formed in the front surface of the shower head may have the same diameter as one another. Each of the spray holes may be connected to a corresponding one of the flow channels so that reaction gas supplied through the flow channels is sprayed outside from the front surface through the spray holes.

In another aspect of the present disclosure, a roll-to-roll plasma-processing apparatus includes a chamber, a drum positioned in the chamber and configured to rotate and to carry a flexible substrate introduced into the chamber along an outer circumferential surface of the drum, and a shower head positioned adjacent to a portion of the outer circumferential surface of the drum.

The shower head may include a body including a plurality of flow channels provided therein and a front surface having a concave shape, and a plurality of spray holes formed in the front surface and having a same diameter as one another. Each of the spray holes may be connected to a corresponding one of the flow channels so that reaction gas supplied through the flow channels is sprayed to the outer circumferential surface of the drum from the front surface through the spray holes.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a view schematically illustrating the construction of a roll-to-roll plasma-processing apparatus according to one or more embodiments of the present disclosure;

FIG. 2 is a perspective view illustrating a front surface of a shower head of the apparatus shown in FIG. 1;

FIG. 3 is a sectional view of the shower head shown in FIG. 2;

FIG. 4A is a partially enlarged view of a portion “A” of the shower head shown in FIG. 3;

FIG. 4B is a partially enlarged view of a portion “B” of the shower head shown in FIG. 3; and

FIG. 4C is a partially enlarged view of a portion “C” of the shower head shown in FIG. 3.

### DETAILED DESCRIPTION

Reference will now be made in detail to the preferred embodiments of the present disclosure, examples of which are illustrated in the accompanying drawings. Wherever possible or convenient for description of the embodiments provided herein, the same reference numbers will be used throughout the drawings to refer to the same or like parts.

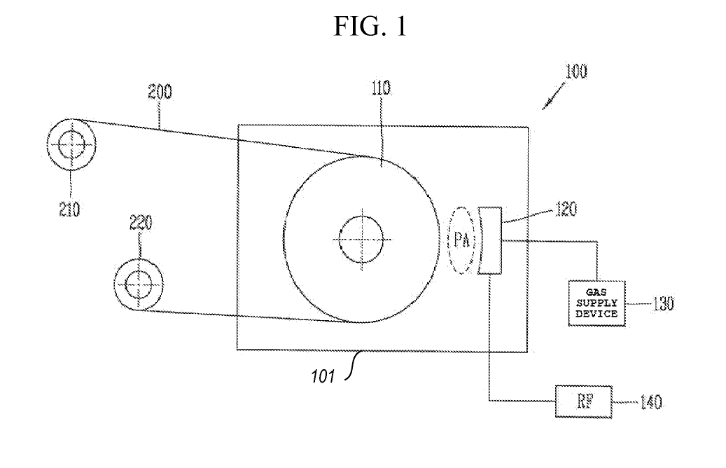

FIG. 1 is a view schematically illustrating the construction of a roll-to-roll plasma-processing apparatus according to one or more embodiments of the present disclosure.

Referring to FIG. 1, a roll-to-roll plasma-processing apparatus 100 according to one or more embodiments may include a chamber 101, and may further include a drum 110 and a shower head 120, which are provided in the chamber 101. The plasma-processing apparatus 100 may serve to form a thin film on a flexible substrate 200, which is introduced therein from an external device, for example, an unwinding roller 210, through a deposition process using plasma and to transfer the flexible substrate 200 having the thin film formed thereon to a rewinding roller 220. Here, the plasma-processing apparatus 100 may be a plasma-enhanced chemical vapor deposition (PECVD) apparatus. The chamber 101 may be configured such that the internal space thereof is maintained in a vacuum state for performing the plasma deposition process.

The drum 110 of the plasma-processing apparatus 100 may be formed in a cylindrical shape. The drum 110 may be configured to rotate in a predetermined direction so that the flexible substrate 200 introduced into the chamber 101 from the unwinding roller 210 travels along the outer circumferential surface of the drum 110 and is transferred to the rewinding roller 220, which is provided outside the chamber 101.

The shower head 120 of the plasma-processing apparatus 100 may be disposed adjacent to a portion of the outer circumferential surface of the drum 110. When a predetermined voltage is applied to the shower head 120 from an external RF voltage source 140, the shower head 120 may spray reaction gas, which is supplied from a gas supply device 130. Accordingly, a plasma area PA is formed between the outer circumferential surface of the drum 110 and the front surface of the shower head 120. While the flexible substrate 200 travels along the outer circumferential surface of the drum 110, a thin film may be deposited on the region of the flexible substrate 200 that corresponds to the plasma area PA.

The front surface of the shower head 120, from which the reaction gas is sprayed, may be formed so as to have a shape corresponding to the outer circumferential surface of the drum 110. That is, the front surface of the shower head 120 may be formed in a concave shape that corresponds to the outer circumferential surface of the cylindrical-shaped drum 110. Specifically, the front surface of the shower head 120 may be a concave surface having the same curvature as the curvature of the outer circumferential surface of the drum 110.

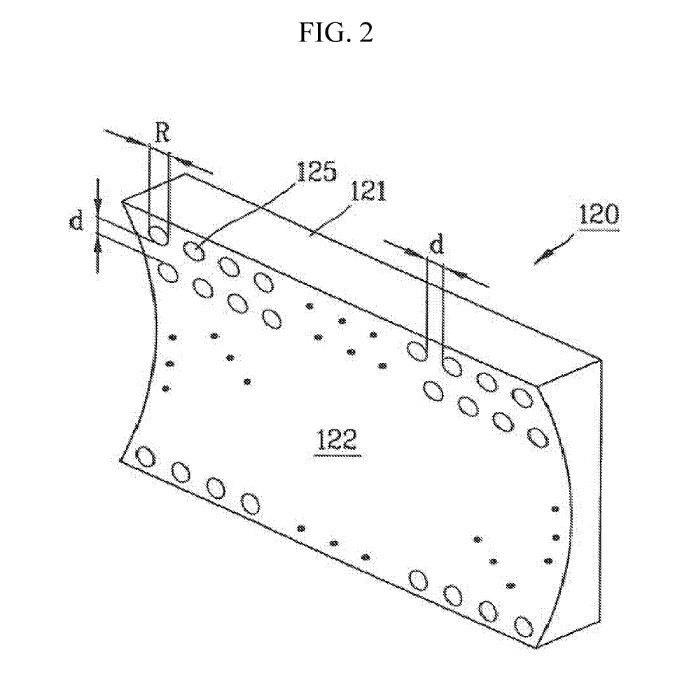

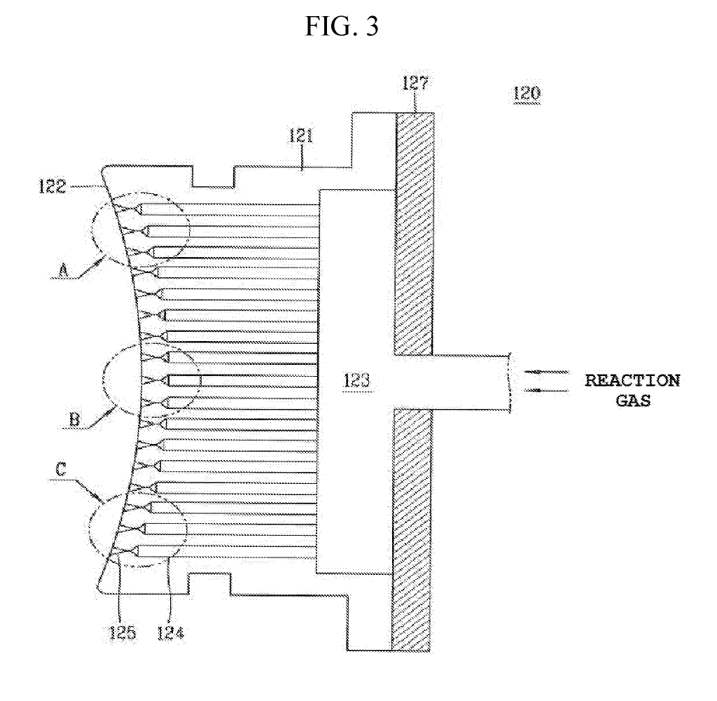

FIG. 2 is a perspective view illustrating a front surface of the shower head shown in FIG. 1, and FIG. 3 is a sectional view of the shower head shown in FIG. 2.

Referring to FIGS. 2 and 3, the shower head 120 of the embodiment may include a body unit 121, which has therein a plurality of spray holes 125 and a plurality of flow channels 124, and an electrode unit 127. The body unit 121 may further include a front surface 122, which is concave with a predetermined curvature and is oriented toward the outer circumferential surface of the drum 110, and a cavity 123 formed therein.

The spray holes 125 may be formed in the front surface 122 of the body unit 121 and may be arranged so as to be spaced equidistantly apart from one another. Each of the spray holes 125 may be connected to one end of a respective one of the flow channels 124, whereby the reaction gas supplied from an external device may be sprayed to the outer circumferential surface of the drum 110 from the front surface 122 of the body unit 121.

The spray holes 125 may be formed so as to have the same diameter R as one another. The spray holes 125 may be formed in various shapes. After the front surface 122 of the body unit 121 is formed in a concave shape, the spray holes 125 may be formed in the front surface 122 through a perforation process. Further, the spray holes 125 may be arranged such that the distances (denoted by “d”) between neighboring spray holes 125 in the vertical direction and the horizontal direction are the same. The diameter R of the spray holes 125 and the distance d therebetween may be set to optimal values that are suitable for the deposition rate of the thin film that is formed on the flexible substrate 200. Specifically, the diameter R of the spray holes 125 and the distance d therebetween may be set to optimal values that are calculated based on the internal pressure of the plasma-processing apparatus 100, the kind of reaction gas, the plasma efficiency, etc.

As such, since the shower head 120 according to the embodiment is configured such that the spray holes 125 formed in the front surface 122 have the same diameter R as one another and are arranged so as to be spaced an equal distance d apart from one another, the amount of reaction gas sprayed through the spray holes 125 may be uniform. Accordingly, it is possible to improve the uniformity of plasma generated by the reaction gas and consequently to increase the deposition rate and the density of the thin film that is formed on the flexible substrate 200.

The flow channels 124, which are provided in the body unit 121, may be arranged so as to be spaced equidistantly apart from one another. Each of the flow channels 124 may be connected at one end thereof to a respective one of the spray holes 125 that are arranged in the front surface 122. The opposite ends of the flow channels 124 may be connected to the cavity 123. Therefore, the flow channels 124 may serve to supply the reaction gas, which is supplied to the cavity 123 from an external device, that is, the gas supply device 130, to the spray holes 125.

The flow channels 124 may be formed so as to have mutually different lengths. In an example, the flow channels 124 that are positioned at the upper and lower end regions of the body unit 121 have greater lengths than the flow channels 124 that are positioned at the middle region of the body unit 121.

Specifically, the lengths of the flow channels 124 may gradually decrease from the top of the body unit 121 to the middle region of the body unit 121, and may gradually increase from the middle region of the body unit 121 to the bottom of the body unit 121. Accordingly, the one ends of the flow channels 124 are not aligned along the same vertical line, but may be arranged corresponding to the curvature of the front surface 122 of the body unit 121. The length of each of the flow channels 124 refers to a length from the one end of each of the flow channels 124 to the opposite end thereof. The one end of each of the flow channels 124 refers to a portion that is connected to the corresponding spray hole 125, and the opposite end of each of the flow channels 124 refers to a portion that is connected to the cavity 123.

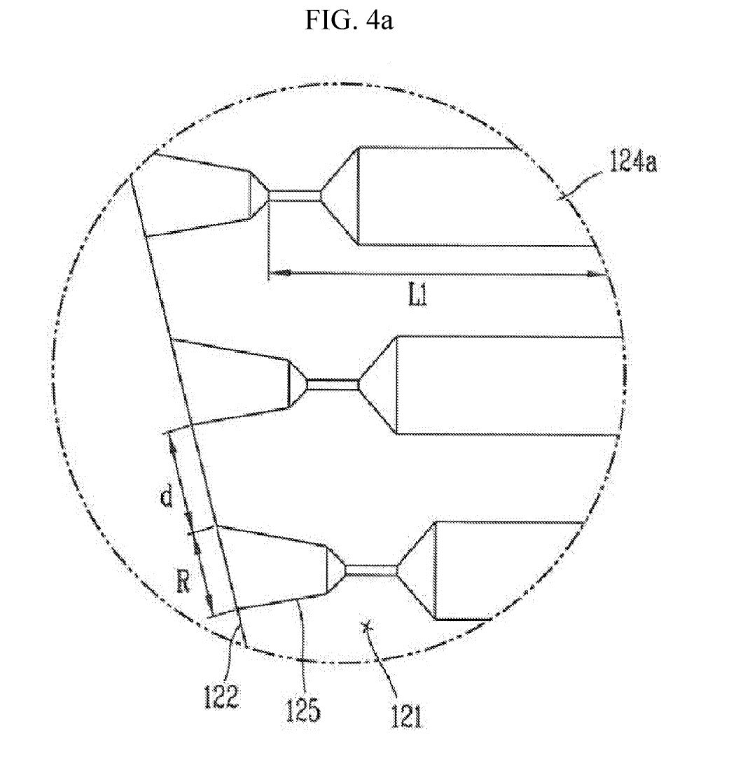

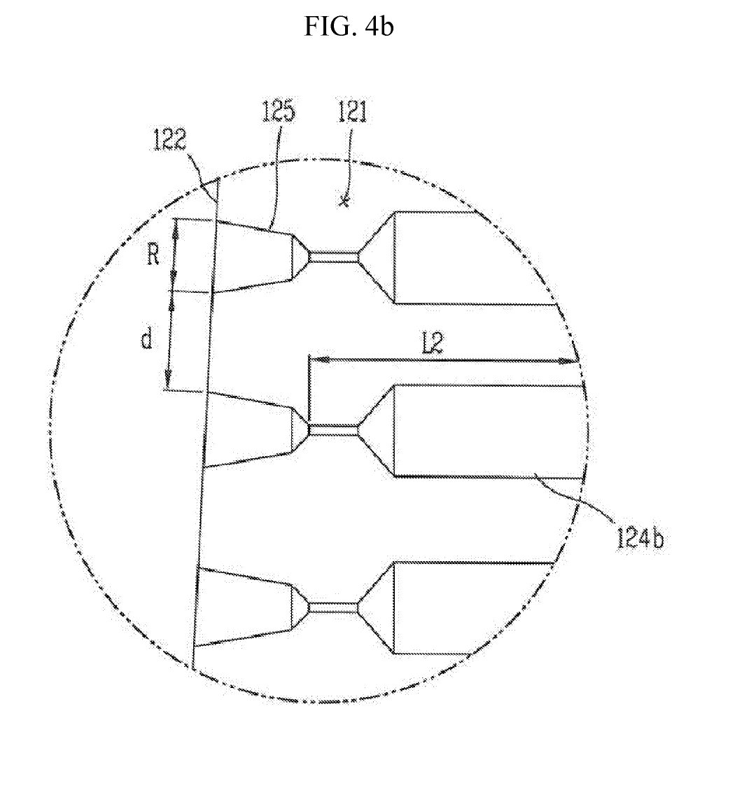

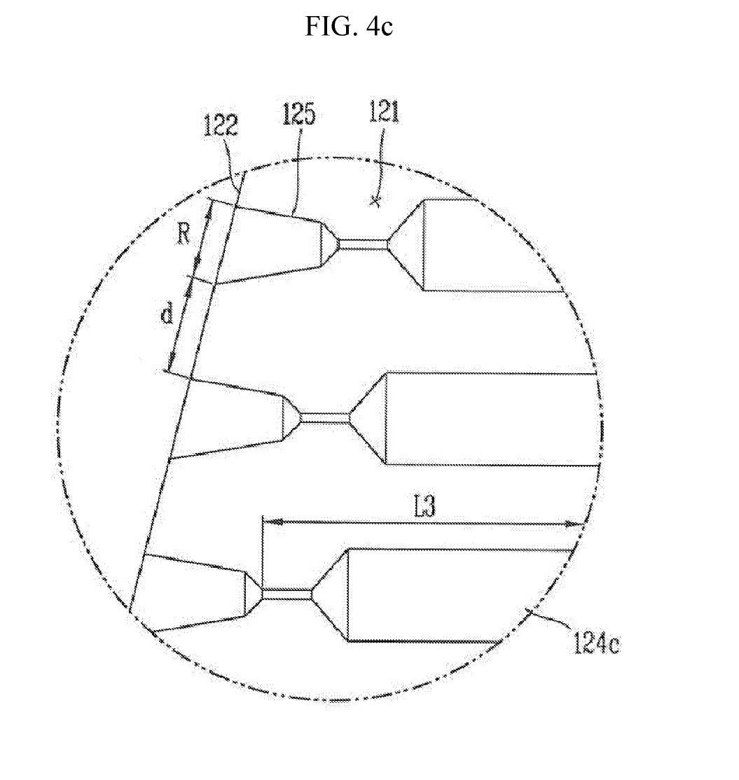

Referring to FIG. 4A, the flow channels 124a that are positioned at the upper end region of the body unit 121 may have mutually different lengths L. Specifically, the lengths L of the flow channels 124a positioned at the upper end region of the body unit 121 gradually decrease from the top of the body unit 121 to the region thereunder. For example, the length L1 of the flow channel 124a at the top position of the body unit 121 is longer than the length of the next flow channel 124 below the top flow channel 124a. Therefore, the one ends of the flow channels 124a positioned at the upper end region of the body unit 121 may be arranged so as to correspond to the curvature of the front surface 122 of the body unit 121.

The spray holes 125 that communicate with the one ends of the corresponding flow channels 124a positioned at the upper end region of the body unit 121 may have the same diameter R as one another, and may be arranged so as to be spaced an equal distance d apart from one another. Further, the depths of the spray holes 125, that is, the lengths from the front surface 122 to the one ends of the flow channels 124a, may be the same as one another.

Referring to FIG. 4B, the flow channels 124b that are positioned at the middle region of the body unit 121 may have substantially the same lengths L2 within an error range. The reason for this is that the curvature of the middle region of the front surface 122 is approximately zero. Therefore, the one ends of the flow channels 124b positioned at the middle region of the body unit 121 may be arranged along a predetermined imaginary line that corresponds to the curvature of the front surface 122 of the body unit 121.

Like the above-described spray holes 125 formed in the upper end region of the body unit 121, the spray holes 125 that communicate with the one ends of the corresponding flow channels 124b positioned at the middle region of the body unit 121 may have the same diameter R and the same depth as one another, and may be arranged so as to be spaced an equal distance d apart from one another.

Referring to FIG. 4C, the flow channels 124c that are positioned at the lower end region of the body unit 121 may have mutually different lengths L. Specifically, the lengths L of the flow channels 124c positioned at the lower end region of the body unit 121 gradually decrease from the bottom of the body unit 121 to the region thereabove. For example, the length L3 of the flow channel 124c at the bottom position of the body unit 121 is longer than the length of the next flow channel 124 directly above the bottom flow channel 124c. Therefore, the one ends of the flow channels 124c positioned at the lower end region of the body unit 121 may be arranged so as to correspond to the curvature of the front surface 122 of the body unit 121.

Like the above-described spray holes 125 formed in the upper end region and the middle region of the body unit 121, the spray holes 125 that communicate with the one ends of the corresponding flow channels 124c positioned at the lower end region of the body unit 121 may have the same diameter R and the same depth as one another, and may be arranged so as to be spaced an equal distance d apart from one another.

In one or more embodiments, the length L1 of the flow channel 124a at the top position of the body unit 121 may be equal to the length L3 of the flow channel 124c at the bottom position of the body unit 121. Moreover, the flow channels 124 may be arranged in one or more corresponding pairs having equal lengths, with each flow channel 124 of a corresponding pair being positioned opposite to another flow channel 124 of the corresponding pair. For example, the top and bottom flow channels 124a, 124c may have a same length, the second to the top and the second to the bottom flow channels may have a same length, and so on.

As described above with reference to FIGS. 3 to 4C, the shower head 120 may be configured such that the front surface 122 thereof may be a concave surface having the same curvature as the curvature of the outer circumferential surface of the drum 110 and such that the spray holes 125 formed in the front surface 122 have the same diameter R and the same depth as one another and are arranged so as to be spaced an equal distance d apart from one another. The flow channels 124a to 124c, which are provided in the body unit 121 and are connected to the corresponding spray holes 125, may be configured such that the lengths L thereof are mutually different, particularly, such that the lengths L thereof gradually increase from the middle region of the body unit 121 to the top and bottom of the body unit 121.

Therefore, the shower head 120 according to the embodiment is capable of ensuring the uniformity of the amount of reaction gas sprayed through the spray holes 125 over the entire area of the front surface 122. As a result, it is possible to improve the uniformity of plasma generated by the reaction gas and consequently to increase the deposition rate and the density of the thin film that is formed on the flexible substrate 200.

Further, since the spray holes 125 in the shower head 120 according to the embodiment are formed so as to have the same depth as one another, when a process of cleaning the shower head 120 is performed, the efficiency of cleaning the inner spaces of the spray holes 125 is improved, thereby reducing process defects.

Referring back to FIG. 3, the electrode unit 127 may be disposed at the rear surface of the body unit 121, specifically, adjacent to the cavity 123. The electrode unit 127 may receive predetermined RF voltage from an external device, for example, the RF voltage source 140. When the RF voltage is applied to the electrode unit 127, the shower head 120 may spray the reaction gas through the spray holes 125 formed in the front surface 122. Accordingly, as shown in FIG. 1, the plasma area PA may be formed between the shower head 120 and the drum 110, whereby a thin film may be deposited on the flexible substrate 200 that travels along the outer circumferential surface of the drum 110.

As is apparent from the above description, the present disclosure provides a shower head, which is configured such that a plurality of spray holes is formed so as to have the same diameter as one another and is arranged so as to be spaced an equal distance apart from one another, thereby ensuring the uniformity of the amount of reaction gas sprayed through the spray holes. As a result, it is possible to improve the uniformity of plasma generated between the shower head and a drum by the reaction gas sprayed from the shower head and consequently to increase the deposition rate and the density of the thin film, which is deposited on the flexible substrate that travels along the drum in a roll-to-roll plasma-processing apparatus.

In addition, since the shower head according to the present disclosure is configured such that the spray holes are formed so as to have the same depth as one another, when a process of cleaning the shower head is performed, the efficiency of cleaning the inner spaces of the spray holes is improved, thereby reducing the incidence of defects in a thin-film deposition process due to contaminants, such as particles that remain in the spray holes.

It will be apparent to those skilled in the art that various modifications and variations can be made in the present disclosure without departing from the spirit or scope of the disclosure. Thus, it is intended that the present disclosure covers the modifications and variations of this disclosure provided they come within the scope of the appended claims and their equivalents.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A shower head for a plasma processing apparatus, comprising:
a body including a plurality of flow channels provided therein and a front surface having a concave shape; and
a plurality of spray holes formed in the front surface and having a same diameter as one another,
wherein each of the spray holes is connected to a corresponding one of the flow channels so that reaction gas supplied through the flow channels is sprayed from the front surface through the spray holes.

2. The shower head according to claim 1, wherein the spray holes are spaced apart from one another by an equal distance.

3. The shower head according to claim 1, wherein each of the spray holes has a same depth between the front surface and the respective corresponding one of the flow channels.

4. The shower head according to claim 1, wherein the flow channels have different lengths corresponding to a curvature of the front surface.

5. The shower head according to claim 4, wherein the lengths of the flow channels gradually increase from a middle region of the body to a top and a bottom of the body.

6. The shower head according to claim 4, wherein an uppermost flow channel and a lowermost flow channel have a same length.

7. The shower head according to claim 1, wherein the body further includes a cavity opposite to the front surface, the cavity being in fluid communication with the plurality of flow channels.

8. A roll-to-roll plasma-processing apparatus, comprising:
a chamber;
a drum positioned in the chamber and configured to rotate and to carry a flexible substrate introduced into the chamber along an outer circumferential surface of the drum; and
a shower head positioned adjacent to a portion of the outer circumferential surface of the drum and configured to spray reaction gas supplied from an external device to generate a plasma area, the shower head including a body including a plurality of flow channels provided therein and a front surface having a concave shape, and a plurality of spray holes formed in the front surface and having a same diameter as one another,
wherein each of the spray holes is connected to a corresponding one of the flow channels so that reaction gas supplied through the flow channels is sprayed to the outer circumferential surface of the drum from the front surface through the spray holes.

9. The roll-to-roll plasma-processing apparatus according to claim 8, wherein the front surface of the body of the shower head is a concave surface having a same curvature as a curvature of the outer circumferential surface of the drum.
